(19) United States
(12) Patent Application Publication
(10) Pub. No.: US 2016/0343546 A1
(43) Pub. Date: Nov. 24, 2016

(54) PLASMA POWER SUPPLY UTILIZING IGNITION CIRCUIT WITH BYPASS SWITCH WITH REACTIVE IMPEDANCE

(71) Applicant: Michael Kishinevsky, North Andover, MA (US)

(72) Inventor: Michael Kishinevsky, North Andover, MA (US)

(21) Appl. No.: 14/720,749

(22) Filed: May 23, 2015

(51) Int. Cl. H01J 37/32; H01J 37/34

(52) U.S. Cl. CPC H01J 37/32064; H01J 37/3405; H01J 2237/332

(57) ABSTRACT

The disclosed invention reduces current in the ignition circuit during normal operation (after ignition) by redirecting portion of the plasma current via a bypass switch.

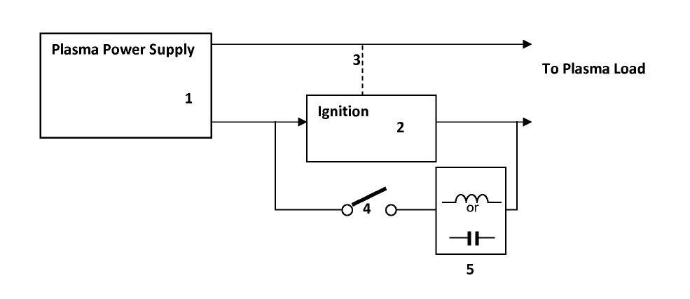

### BACKGROUND OF THE INVENTION

The disclosed invention pertains to the field of alternate current plasma power supplies used in vacuum coating equipment and other applications.

It is well known to those skilled in the art that In order to start the gas discharge (plasma) often a higher voltage is needed than that required to sustain the discharge. One common method of achieving plasma ignition is to insert a voltage source in series with the main power supply to temporarily boost the load voltage until plasma is established. However, additional cost is often incurred in such an igniter because it is required to conduct full load current after the ignition.

A simple bypass switch can solve this problem, however such a switch would need to conduct the entire load current without using the igniter current capacity. The disclosed invention shares the current between the bypass switch and the ignition circuit using low-loss reactive impedance thus helping to optimize system cost and size.

### BRIEF SUMMARY OF THE INVENTION

The present invention puts a bypass switch connected in series with a low los reactive impedance device, such as inductor or a capacitor, around the series-connected ignition circuit. By properly choosing the value of the reactive device, current flow distribution between the ignition circuit and the switch can be optimized to minimize the total system cost and/or size.

### BRIEF DESCRIPTION OF THE DRAWING

One lead of the main power supply 1 is connected to the load and the second lead to the ignition circuit 2 and the bypass switch 4. The current in the bypass switch is limited by the reactive impedance device 5 that can be capacitive or inductive. The ignition circuit 2 can get power need for its operation from the first lead of the power supply as depicted by the optional connection 3 (dashed line), or from other connections that are omitted for clarity.

### DETAILED DESCRIPTION OF THE INVENTION

The switch has to be controlled in such as way as to keep it open during ignition process and then close it after plasma has started. The switch can be an electro-mechanical relay or made out of one or more semiconductor power switching devices.

The switch has to be sized to sustain the plasma current during normal operation, reduced by amount of current conducted by the ignition circuit.

The optimal impedance value of the reactive series impedance device depends on the ignition circuit impedance, and the ratio of the two impedances sets the relative amount of current share between the two paths.

Ideally, the current share of the ignition circuit should be equal to its current carrying capacity and the switch sized for the reminder of the load current.

We claim:

1. A power delivery system for use with a plasma load, comprising:
a. An alternate current or pulsed bipolar power supply that provides voltage and current for the plasma load.
b. An ignition circuit that provides additional voltage to the load during ignition in series with the power supply having first lead connected to the power supply, second lead connected to the load and zero or more additional leads for supplying control signals and power to said ignition circuit.
c. A bypass switch having first lead connected to a first lead of a fixed reactive impedance, with second lead of said switch and second lead of said reactive connected to said first and second leads of said ignition circuit after, said switch open during ignition and closed during normal run after ignition.

2. A power delivery system as recited in claim where in a third lead of said ignition circuit is connected to the other output of said power supply in order to provide power for operation of said ignition circuit.

3. A power delivery system as recited in claim 2, used in vacuum coating equipment.

4. A power delivery system as recited in claim 3 used in magnetron sputtering equipment.

5. A power delivery system as recited in claim 4 wherein said reactive impedance is a capacitor.

6. A power delivery system as recited in claim 4 wherein said reactive impedance is an inductor.

7. A power delivery system as recited in claim 6 wherein said switch is also connected to control signals that control it to be open during ignition and closed after ignition.

8. A power delivery system as recited in claim 7 wherein said switch is a relay.

9. A power delivery system as recited in claim 7 wherein said switch is comprised of one or more semiconductor devices, such as FET, diode, IGBT, bipolar transistor or BiMOS transistor.
